(19) United States
(12) Patent Application Publication
(10) Pub. No.: US 2024/0381589 A1
(43) Pub. Date: Nov. 14, 2024

(54) DATA CENTER COOLING SYSTEM, CONTROL METHOD, AND DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/657,332

(22) Filed: May 7, 2024

(30) Foreign Application Priority Data
May 11, 2023 (CN) 202310531303.5

(51) Int. Cl. H05K 7/20

(52) U.S. Cl. CPC H05K 7/20836; H05K 7/20309; H05K 7/20318; H05K 7/20327; H05K 7/208

(57) ABSTRACT

The present disclosure discloses a data center cooling system, a control method, and a data center. The system includes: a psychrometer arranged in the data center; a first plate cooler connected to the data center; a mechanical refrigerating device, where a water inlet end of the mechanical refrigerating device is connected to the water outlet end of the first plate cooler through a second branch, and a water outlet end of the mechanical refrigerating device is connected to the water inlet end of the data center; a cooling tower configured to form a cooling water circulation with the first plate cooler and to form a refrigerant circulation with the mechanical refrigerating device; a first solenoid valve arranged on the first branch; and a second solenoid valve arranged on the second branch.

### CROSSREFERENCE TO RELATED APPLICATION

This application claims priority to Chinese Patent Application No. 202310531303.5, titled “DATA CENTER COOLING SYSTEM, CONTROL METHOD, AND DATA CENTER” and filed to the China National Intellectual Property Administration on May 11, 2023, the entire contents of which are incorporated herein by reference.

### TECHNICAL FIELD

The present disclosure relates to the field of cooling technology, and more particularly, to a data center cooling system, a control method, and a data center.

### BACKGROUND

With the development of the data center industry, people have increasing demands for power usage effectiveness (PUE).

At present, data center cooling systems adopt a solution where mechanical refrigerating modules and composite evaporative cooling modules are connected in series for operation.

This solution has higher power consumption, larger engineering quantity, and complex control logic.

### SUMMARY

The present disclosure provides a data center cooling system, a control method, and a data center, which can integrate a mechanical refrigerating device with a composite evaporative cooling module, simplify workload of on-site construction, installation, and transportation, simplify control logic of the cooling system, and reduce energy consumption of the cooling system.

In a first aspect, embodiments of the present disclosure provide a data center cooling system, which includes:
a psychrometer arranged in a data center, where the psychrometer is configured to detect a dry-bulb temperature and a wet-bulb temperature inside the data center;
a first plate cooler, where a water inlet end of the first plate cooler is connected to a water outlet end of the data center, a water outlet end of the first plate cooler is connected to a water inlet end of the data center through a first branch, and the first plate cooler is configured to carry out primary cooling on circulating water in the data center;
a mechanical refrigerating device, where a water inlet end of the mechanical refrigerating device is connected to the water outlet end of the first plate cooler through a second branch, a water outlet end of the mechanical refrigerating device is connected to the water inlet end of the data center, and the mechanical refrigerating device is configured to carry out secondary cooling on the circulating water;
a cooling tower configured to form a cooling water circulation with the first plate cooler and to form a refrigerant circulation with the mechanical refrigerating device;
a first solenoid valve arranged on the first branch, where the first solenoid is configured to control to open or close the first branch based on a detection result of the psychrometer; and
a second solenoid valve arranged on the second branch, where the second solenoid is configured to control to open or close the second branch based on the detection result of the psychrometer.

Alternatively, the mechanical refrigerating device includes:
a fluorine pump, where a liquid inlet end of the fluorine pump is connected to the cooling tower, a liquid outlet end of the fluorine pump is connected to a liquid inlet end of an evaporator, and the fluorine pump is configured to transport a refrigerant to the evaporator;
the evaporator, where a water inlet end of the evaporator is connected to the water outlet end of the first plate cooler, a water outlet end of the evaporator is connected to the water outlet end of the data center through the second branch, and the evaporator is configured to carry out secondary cooling on the circulating water through the liquid refrigerant; and
a first bypass valve connected in parallel to one side of the fluorine pump.

Alternatively, the mechanical refrigerating device also includes:
a compressor, where a liquid outlet end of the compressor is connected to the cooling tower, a liquid inlet end of the compressor is connected to a liquid outlet end of the evaporator, and the compressor is configured to increase pressure of refrigerant vapor inside the evaporator and extract the refrigerant vapor into the cooling tower. A second bypass valve is connected in parallel to one side of the compressor.

Alternatively, the cooling tower includes:
a condenser configured to condense the cooling water such that the condensed cooling water flows into a packing under gravity, where the condenser is also configured to condense the refrigerant vapor such that the condensed refrigerant vapor flows into the mechanical refrigerating device under gravity;
the packing arranged below the condenser, where the packing is configured to extend residence time of the cooling water and to increase a heat transfer area of the cooling water;
a pre-cooling section arranged below the condenser, where the pre-cooling section is configured to cool the cooling water; and
a spray pump configured to spray the pre-cooling section.

Alternatively, the system also includes:

a cooling water pump, where a water inlet end of the cooling water pump is connected to the first plate cooler, and a water outlet end of the cooling water pump is connected to a water inlet end of the cooling tower.

Alternatively, the system also includes:
a second plate cooler, where a water inlet end of the second plate cooler is connected to the water outlet end of the data center, a water outlet end of the second plate cooler is connected to the water inlet end of the data center through a third branch, and the second plate cooler is configured to cool the circulating water in the data center; and
a third solenoid valve arranged in the third branch, where the third solenoid valve is configured to control to open or close the third branch based on the detection result of the psychrometer.

Alternatively, the cooling tower also includes:
a dry cooler arranged above the condenser and connected to the second plate cooler, where the dry cooler is configured to cool the circulating water.

In a second aspect, the embodiments of the present disclosure provide a control method for the data center cooling system as described in the first aspect. The control method includes:
obtaining a dry-bulb temperature and a wet-bulb temperature inside the data center;
when the dry-bulb temperature is lower than a first threshold, controlling the second solenoid valve to be switched on, the first solenoid valve to be switched off, and the cooling water pump to be switched off;
when the dry-bulb temperature is not lower than the first threshold and the wet-bulb temperature is lower than a second threshold, controlling the first solenoid valve to be switched on, the second solenoid valve to be switched off, and the cooling water pump to be switched on; and
when the wet-bulb temperature is not lower than a third threshold, controlling the second solenoid valve to be switched on, the first solenoid valve to be switched off, and the cooling water pump to be switched on.

Alternatively, the method also includes:
when the dry-bulb temperature is lower than the first threshold, controlling the first solenoid valve to be switched off, the second solenoid valve to be switched off, the cooling water pump to be switched off, and the third solenoid valve to be switched on.

In a third aspect, the embodiments of the present disclosure provide a data center, which includes the data center cooling system as described in the first aspect.

In the above technical solutions, the data center cooling system is provided with the first plate cooler, the mechanical refrigerating device, and the cooling tower. Thus, the mechanical refrigerating device can be integrated with the composite evaporative cooling module, the architecture of the cooling system can be simplified, the workload of on-site construction, installation and transportation can be reduced, and the control logic of the cooling system can be simplified. Furthermore, the mechanical refrigerating device and the cooling tower can run in different time periods and situations based on the dry-bulb temperature and the wet-bulb temperature, thereby reducing the energy consumption of the cooling system.

### BRIEF DESCRIPTION OF THE DRAWINGS

To describe the technical solutions of the embodiments of the present disclosure more clearly, the accompanying drawings required in the description of the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a data center cooling system according to an embodiment of the present disclosure;

FIG. 2 is a schematic structural diagram of another data center cooling system according to an embodiment of the present disclosure;

FIG. 3 is a flowchart of a control method for a data center cooling system according to an embodiment of the present disclosure; and

FIG. 4 is a flowchart of a control method for another data center cooling system according to an embodiment of the present disclosure.

### REFERENCE NUMERALS IN THE ACCOMPANYING DRAWINGS

data center 10; first plate cooler 20; second plate cooler 21; mechanical refrigerating device 30; evaporator 31; compressor 32; fluorine pump 33; cooling tower 40; condenser 41; spray pump 42; re-cooling section 43; packing 44; water tray 45; dry cooler 46; cooling water pump 50; first solenoid valve V1; second solenoid valve V2; third solenoid valve V3; first bypass valve P1; and second bypass valve P2.

### DETAILED DESCRIPTION

To make the objectives, technical solutions and advantages of the present disclosure clearer, the embodiments of the present disclosure will be further described in detail below with reference to the accompanying drawings.

At present, data center cooling systems adopt a solution where a mechanical refrigerating module and a composite evaporative cooling module are connected in series for operation, where a composite evaporative cooling unit is a unit for cooling by means of a condenser.

For users, this solution requires larger workload and larger energy consumption for the cooling systems.

In view of this, embodiments of the present disclosure provide a data center cooling system, a control method, and a data center. The mechanical refrigerating module is integrated with the composite evaporative cooling unit, such that the workload of on-site construction, installation and transportation of the cooling system can be reduced. Furthermore, a mechanical refrigerating device and a cooling tower can run in different time periods based on a dry-bulb temperature and a wet-bulb temperature, thereby reducing the energy consumption of the cooling system.

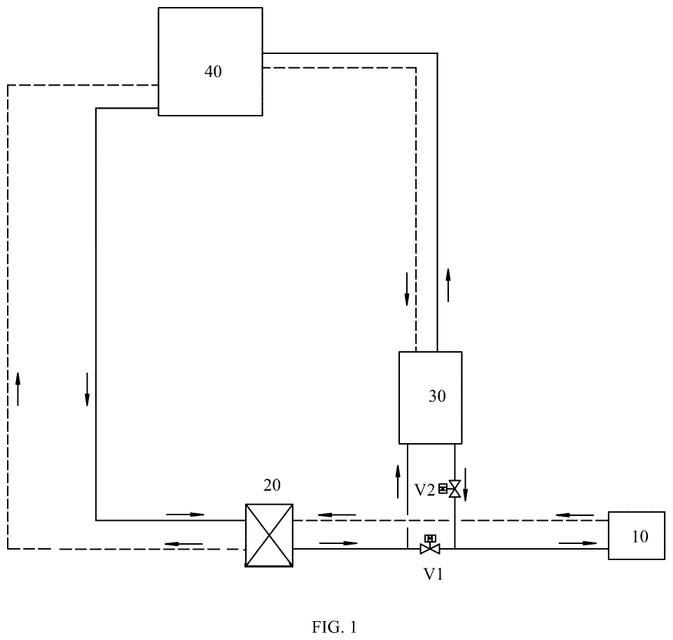

The embodiments of the present disclosure provide a data center cooling system, and FIG. 1 is a schematic structural diagram of the data center cooling system according to the embodiments of the present disclosure. As shown in FIG. 1, the data center cooling system includes:
a psychrometer arranged in a data center 10, where the psychrometer is configured to detect the dry-bulb temperature and the wet-bulb temperature inside the data center 10;
a first plate cooler 20, where a water inlet end of the first plate cooler 20 is connected to a water outlet end of the data center 10, a water outlet end of the first plate cooler 20 is connected to a water inlet end of the data center 10 through a first branch, and the first plate cooler 20 is configured to carry out primary cooling on circulating water in the data center 10;
a mechanical refrigerating device 30, where a water inlet end of the mechanical refrigerating device 30 is connected to the water outlet end of the first plate cooler 20 through a second branch, a water outlet end of the mechanical refrigerating device 30 is connected to the water inlet end of the data center 10, and the mechanical refrigerating device 30 is configured to carry out secondary cooling on the circulating water;
a cooling tower 40 configured to form a cooling water circulation with the first plate cooler 20 and to form a refrigerant circulation with the mechanical refrigerating device 30;
a first solenoid valve V1 arranged on the first branch, where the first solenoid V1 is configured to control to open or close the first branch based on a detection result of the psychrometer; and
a second solenoid valve V2 arranged on the second branch, where the second solenoid V2 is configured to control to open or close the second branch based on the detection result of the psychrometer.

For example, the dry-bulb temperature and the wet-bulb temperature inside the data center 10 may be detected by means of other instruments.

When the psychrometer detects that the dry-bulb temperature and the wet-bulb temperature inside the data center 10 meet a first preset condition, the first solenoid valve V1 is switched off, and the second solenoid valve V2 is switched on. In this case, after passing through the first plate cooler 20, the circulating water in the data center 10 may flow through the mechanical refrigerating device 30 for cooling. The cooled circulating water flows back to the data center 10 through the second branch where the second solenoid valve V2 is arranged. This cooling mode is a waterless natural cooling mode.

When the psychrometer detects that the dry-bulb temperature and the wet-bulb temperature inside the data center 10 meet a second preset condition, the first solenoid valve V1 is switched on, and the second solenoid valve V2 is switched off. In this case, after being subjected to primary cooling by the first plate cooler 20, the cooled circulating water in the data center 10 flows back to the data center 10 through the first branch where the first solenoid valve V1 is arranged. This cooling mode is an evaporative cooling mode. In this cooling mode, the cooling tower 40 and the first plate cooler 20 form the cooling water circulation to cool the circulating water flowing through the first plate cooler 20. In this cooling mode, the cooling tower 40 and the first plate cooler 20 form a cooling water circulation to cool the circulating water flowing through the first plate cooler 20.

When the psychrometer detects that the dry-bulb temperature and the wet-bulb temperature inside the data center 10 meet a third preset condition, the first solenoid valve V1 is switched off, and the second solenoid valve V2 is switched on. In this case, after being subjected to the primary cooling by the first plate cooler 20, the circulating water in the data center 10 flows through the mechanical refrigerating device 30 for secondary cooling. A refrigerant in the mechanical refrigerating device 30 flows through the cooling tower 40 for cooling, and then flows back to the mechanical refrigerating device 30 under gravity, to cool the circulating water flowing through the mechanical refrigerating device 30. Next, the circulating water flows back to the data center 10 through the second branch where the second solenoid valve V2 is arranged. This cooling mode is a mechanical refrigeration mode. In this cooling mode, the cooling tower 40 and the mechanical refrigerating device 30 form the refrigerant circulation to cool the circulating water flowing through the mechanical refrigerating device 30. In this cooling mode, the cooling tower 40 and the first plate cooler 20 form the cooling water circulation to cool the circulating water flowing through the first plate cooler 20.

For example, the first preset condition may be that the dry-bulb temperature is lower than a first threshold. The second preset condition may be that the dry-bulb temperature is not lower than the first threshold and the wet-bulb temperature is lower than a second threshold. The third preset condition may be that the wet-bulb temperature is not lower than a third threshold. The first threshold, the second threshold, and the third threshold may be determined according to actual scenes, and are not limited by the present disclosure.

In the above technical solutions, the data center cooling system is provided with the first plate cooler, the mechanical refrigerating device, and the cooling tower. Thus, the mechanical refrigerating device can be integrated with the composite evaporative cooling module, the architecture of the cooling system can be simplified, the workload of on-site construction, installation and transportation can be reduced, and the control logic of the cooling system can be simplified. Furthermore, the mechanical refrigerating device and the cooling tower can run in different time periods and situations based on the dry-bulb temperature and the wet-bulb temperature, thereby reducing the energy consumption of the cooling system.

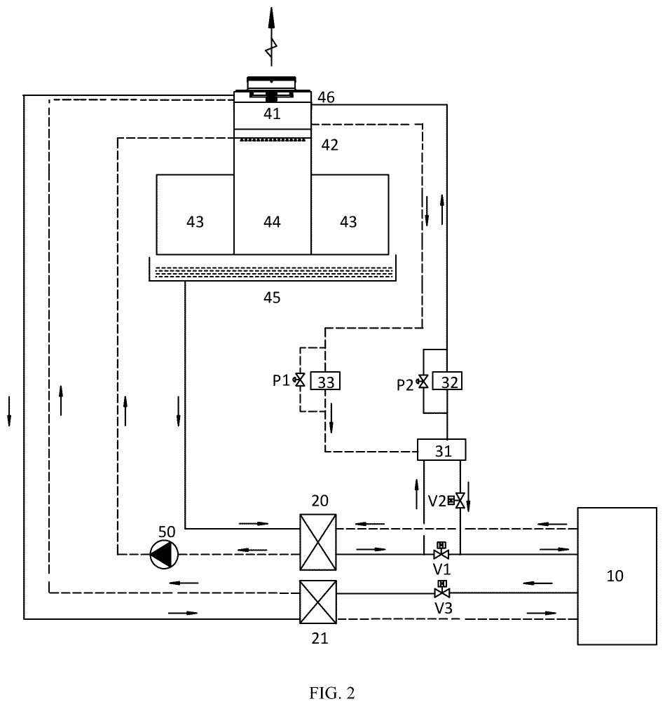

As shown in FIG. 2, the mechanical refrigerating device 30 includes:
a fluorine pump 33, where a liquid inlet end of the fluorine pump 33 is connected to the cooling tower 40, a liquid outlet end of the fluorine pump 33 is connected to a liquid inlet end of an evaporator 31, and the fluorine pump 33 is configured to transport the refrigerant to the evaporator 31; and
the evaporator 31, where a water inlet end of the evaporator 31 is connected to the water outlet end of the first plate cooler 20, a water outlet end of the evaporator 31 is connected to the water outlet end of the data center 10 through the second branch, and the evaporator 31 is configured to cool the circulating water through the liquid refrigerant.

A first bypass valve P1 is connected in parallel to one side of the fluorine pump 33.

In the waterless natural cooling mode, the first bypass valve P1 is switched off, and the fluorine pump 33 is in the operating state. After being cooled by the first plate cooler 20, the circulating water flows through the evaporator 31. The refrigerant in the evaporator 31 absorbs heat of the circulating water and vaporizes into refrigerant vapor. The refrigerant vapor enters the cooling tower 40 for cooling. Next, the cooled refrigerant flows back to the fluorine pump 33 under gravity and enters the evaporator 31, where it absorbs the heat of the circulating water again, and vaporizes into the refrigerant vapor. In this way, the temperature of the circulating water is reduced, thereby achieving the effect of cooling the circulating water. The heat absorbed by the refrigerant vapor is transported outdoors by a fan.

In this way, energy consumption in the waterless natural cooling mode includes energy consumption of the fluorine pump 33 and energy consumption of the fan. Compared with the mechanical refrigerating module and the composite evaporative cooling module connected in series, the energy consumption of the data center cooling system is reduced.

In one embodiment, the mechanical refrigerating device 30 also includes:
a compressor 32, where a liquid outlet end of the compressor 32 is connected to the cooling tower 40, a liquid inlet end of the compressor 32 is connected to a liquid outlet end of the evaporator 31, and the compressor 32 is configured to increase pressure of refrigerant vapor inside the evaporator 31 and extract the refrigerant vapor into the cooling tower 40. A second bypass valve P2 is connected in parallel to one side of the compressor 32.

In the mechanical refrigeration mode, the second bypass valve P2 is switched off, the first bypass valve P1 is switched on, and the compressor 32 is in an operating state. In this cooling mode, the circulating water cooled by the first plate cooler 20 flows into the evaporator 31, and the refrigerant vapor inside the evaporator 31 flows into the compressor 32. In this case, the low-pressure refrigerant vapor inside the evaporator 31 is compressed into high-pressure refrigerant vapor to enter the cooling tower 40 for condensation. The condensed refrigerant enters the evaporator 31 through the first bypass valve P1, absorbs heat and vaporizes, and exchanges heat with the circulating water. In this way, the temperature of the circulating water is reduced, thereby achieving the effect of cooling the circulating water.

The compressor may be supplied by commercial power, so the energy consumption in the mechanical refrigeration mode may be the energy consumption of the compressor. The compressor may be used in conjunction with a cold storage tank in the cooling system, where the cold storage tank may be provided according to duration of mains outage, thereby meeting demands for uninterrupted refrigeration of the entire cooling system.

In one embodiment, the cooling tower 40 includes:
a condenser 41 configured to condense the cooling water such that the condensed cooling water flows into a packing 44 under gravity, where the condenser 41 is also configured to condense the refrigerant such that the condensed refrigerant vapor flows into the mechanical refrigerating device 30 under gravity;
the packing 44 arranged below the condenser 41, where the packing 44 is configured to extend residence time of the cooling water and to increase a heat transfer area of the cooling water;
a pre-cooling section 43 arranged below the condenser 41, where the pre-cooling section 43 is configured to cool the cooling water; and
a spray pump 42 configured to spray the pre-cooling section 43.

The pre-cooling section 43 may be selected according to outdoor operating conditions and water supply temperature.

In the evaporative cooling mode, the circulating water in the data center 10 flows through the first plate cooler 20 and exchanges heat with the cooling water in the first plate cooler 20. After the heat exchange, the cooling water enters the cooling tower 40, such that the condenser 41 condenses the cooling water, and the condensed cooling water flows into the pre-cooling section 43 under gravity. In this case, the spray pump 42 is in an on state. The cooling water cooled by the spray pump 42, the pre-cooling section 43 and the packing 44 exchanges heat with outdoor air in a water tray 45, thereby prolonging time of the cooling water, increasing the heat transfer area of the cooling water, increasing heat dissipation, and reducing the temperature of the cooling water.

The mechanical refrigerating device 30 may be the evaporator 31. When the cooling mode is the mechanical refrigeration mode, the pressurized refrigerant vapor enters the condenser 41 to condense the refrigerant vapor, and the condensed refrigerant flows into the evaporator 31 under gravity to exchange heat with the circulating water in the evaporator. In this way, the temperature of the circulating water is reduced, thereby achieving the effect of secondary cooling of the circulating water.

In one embodiment, the system also includes:
a cooling water pump 50, where a water inlet end of the cooling water pump 50 is connected to the first plate cooler 20, and a water outlet end of the cooling water pump 50 is connected to a water inlet end of the cooling tower 40.

For example, in the waterless natural cooling mode and the mechanical refrigeration mode, the cooling water pump 50 is switched off.

In the evaporative cooling mode, the cooling water pump 50 is switched on, and the circulating water flowing through the first plate heat exchanger 20 exchanges heat with the cooling water in the first plate cooler 20 to cool the circulating water. After the heat exchange, the cooling water enters the cooling tower 40 under the action of the cooling water pump 50. After being sprayed by the spray pump 42, cooled by the pre-cooling section 43, and subjected to heat exchange by the packing 44, the cooling water exchanges heat with the air (supplied by the fan) in the water tray 45, and then flows back to the first plate heat exchanger 20. The fan and the cooling water pump 50 are both provided with a UPS power supply. In this way, energy consumption in the evaporative cooling mode includes energy consumption of the cooling water pump 50 and energy consumption of the fan. Compared with the mechanical refrigerating module and the composite evaporative cooling module connected in series, the energy consumption of the data center cooling system is reduced.

In one embodiment, the system also includes:
a second plate cooler 21, where a water inlet end of the second plate cooler 21 is connected to the water outlet end of the data center 10, a water outlet end of the second plate cooler 21 is connected to the water inlet end of the data center 10 through a third branch, and the second plate cooler 21 is configured to cool the circulating water in the data center 10; and
a third solenoid valve V3 arranged in the third branch, where the third solenoid valve V3 is configured to control to open or close the third branch based on the detection result of the psychrometer.

When the psychrometer detects that the dry-bulb temperature and the wet-bulb temperature inside the data center 10 meet the third preset condition, the third solenoid valve V3 may be controlled to be switched on, and the circulating water in the data center 10 flows through the second plate cooler 21 to cool the circulating water. This cooling mode is a dry condition cooling mode.

It is to be understood that when the dry-bulb temperature is lower than the first threshold, the third solenoid valve V3 may be switched on separately, or the second solenoid valve V2 may be switched on separately, or the second solenoid valve V2 and the third solenoid valve V3 may be switched on simultaneously.

In one embodiment, the cooling tower 40 also includes:
a dry cooler 46 arranged above the condenser 41 and connected to the second plate cooler 21, where the dry cooler 46 is configured to cool the circulating water.

In the dry condition cooling mode, the circulating water in data center 10 flows through the second plate cooler 21 and then exchanges heat with the cooling water in the second plate cooler 21 to cool the circulating water. After the heat exchange, the cooling water flows into the dry cooler 46 under the action of a dry cooler pump, such that the cooling water inside the dry cooler 46 is cooled by the air outside the dry cooler 46, to reduce the temperature of the cooling water. Energy consumption in the dry condition cooling mode only includes energy consumption of the dry cooler pump, thereby reducing the energy consumption of the cooling system.

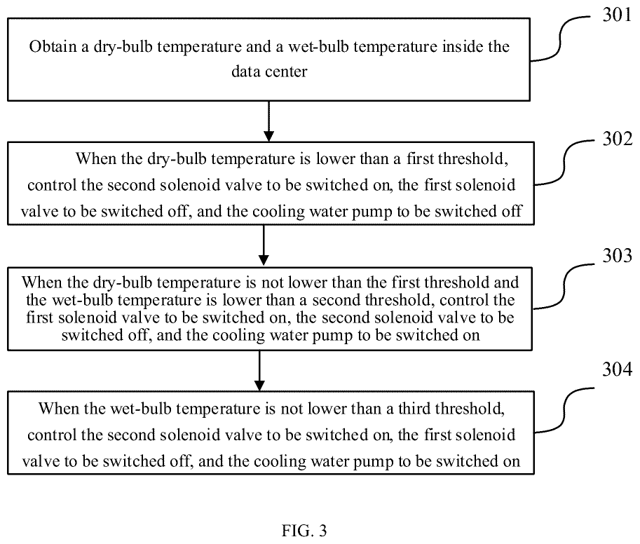

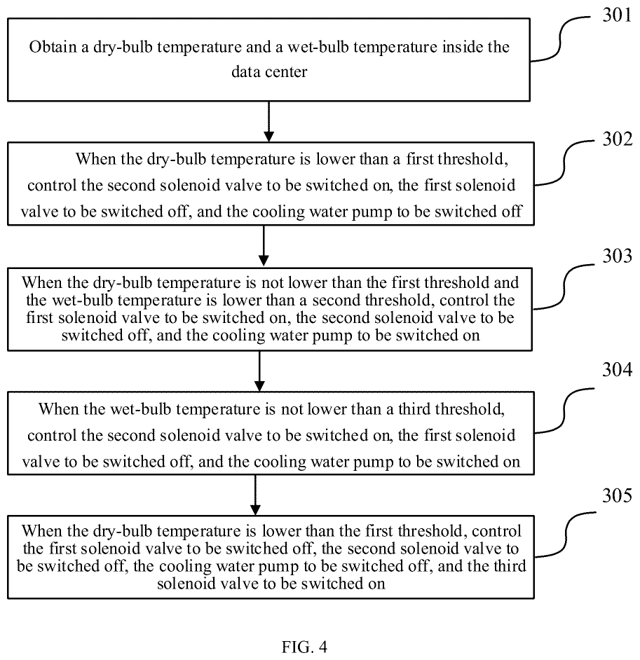

The embodiments of the present disclosure provide a control method for the data center cooling system as described above. FIG. 3 is a flowchart of the control method for the data center cooling system according to the embodiments of the present disclosure. As shown in FIG. 3 and FIG. 4, the control method for the data center cooling system includes following steps.

In Step S301, a dry-bulb temperature and a wet-bulb temperature inside the data center 10 are obtained.

In Step S302, when the dry-bulb temperature is lower than a first threshold, the second solenoid valve V2 is controlled to be switched on, the first solenoid valve V1 is controlled to be switched off, and the cooling water pump 50 is controlled to be switched off.

In Step S303, when the dry-bulb temperature is not lower than the first threshold and the wet-bulb temperature is lower than a second threshold, the first solenoid valve V1 is controlled to be switched on, the second solenoid valve V2 is controlled to be switched off, and the cooling water pump 50 is controlled to be switched on.

In Step S304, when the wet-bulb temperature is not lower than a third threshold, the second solenoid valve V2 is controlled to be switched on, the first solenoid valve V1 is controlled to be switched off, and the cooling water pump 50 is controlled to be switched on.

In one embodiment, the method also includes a step as below.

In Step S305, when the dry-bulb temperature is lower than the first threshold, the first solenoid valve V1 is controlled to be switched off, the second solenoid valve V2 is controlled to be switched off, the cooling water pump 50 is controlled to be switched off, and the third solenoid valve V3 is controlled to be switched on.

The embodiments of the present disclosure provide a data center, which includes the data center cooling system as described above.

Other embodiments of the present disclosure will be apparent to those skilled in the art from consideration of the specification and practice of the invention disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

It is to be appreciated that the present disclosure is not limited to the exact construction that has been described above and illustrated in the accompanying drawings, and that various modifications and changes can be made without departing from the scope thereof. It is intended that the scope of the present disclosure only be limited by the appended claims.

What is claimed is:

1. A data center cooling system, wherein the system comprises:
a psychrometer arranged in a data center, the psychrometer being configured to detect a dry-bulb temperature and a wet-bulb temperature inside the data center;
a first plate cooler, a water inlet end of the first plate cooler being connected to a water outlet end of the data center, a water outlet end of the first plate cooler being connected to a water inlet end of the data center through a first branch, and the first plate cooler being configured to carry out primary cooling on circulating water in the data center;
a mechanical refrigerating device, a water inlet end of the mechanical refrigerating device being connected to the water outlet end of the first plate cooler through a second branch, a water outlet end of the mechanical refrigerating device being connected to the water inlet end of the data center, and the mechanical refrigerating device being configured to carry out secondary cooling on the circulating water;
a cooling tower configured to form a cooling water circulation with the first plate cooler and to form a refrigerant circulation with the mechanical refrigerating device;
a first solenoid valve arranged on the first branch, the first solenoid being configured to control to open or close the first branch based on a detection result of the psychrometer; and
a second solenoid valve arranged on the second branch, the second solenoid being configured to control to open or close the second branch based on the detection result of the psychrometer.

2. The system according to claim 1, wherein the mechanical refrigerating device comprises:
a fluorine pump, a liquid inlet end of the fluorine pump being connected to the cooling tower, a liquid outlet end of the fluorine pump being connected to a liquid inlet end of an evaporator, and the fluorine pump being configured to transport a refrigerant to the evaporator; and
the evaporator, a water inlet end of the evaporator being connected to the water outlet end of the first plate cooler, a water outlet end of the evaporator being connected to the water outlet end of the data center through the second branch, and the evaporator being configured to carry out secondary cooling on the circulating water through the liquid refrigerant;
wherein a first bypass valve is connected in parallel to one side of the fluorine pump.

3. The system according to claim 2, wherein the mechanical refrigerating device further comprises:
a compressor, a liquid outlet end of the compressor being connected to the cooling tower, a liquid inlet end of the compressor being connected to a liquid outlet end of the evaporator, the compressor being configured to increase pressure of refrigerant vapor inside the evaporator and extract the refrigerant vapor into the cooling tower; and a second bypass valve being connected in parallel to one side of the compressor.

4. The system according to claim 1, wherein the cooling tower comprises:
a condenser configured to condense the cooling water such that the condensed cooling water flows into a packing under gravity, the condenser being further configured to condense the refrigerant vapor such that the condensed refrigerant vapor flows into the mechanical refrigerating device under gravity;
the packing arranged below the condenser, the packing being configured to extend residence time of the cooling water and to increase a heat transfer area of the cooling water;
a pre-cooling section arranged below the condenser, the pre-cooling section being configured to cool the cooling water; and
a spray pump configured to spray the pre-cooling section.

5. The system according to claim 1 further comprising:
a cooling water pump, a water inlet end of the cooling water pump being connected to the first plate cooler, and a water outlet end of the cooling water pump being connected to a water inlet end of the cooling tower.

6. The system according to claim 1 further comprising:
a second plate cooler, a water inlet end of the second plate cooler being connected to the water outlet end of the data center, a water outlet end of the second plate cooler being connected to the water inlet end of the data center through a third branch, and the second plate cooler being configured to cool the circulating water in the data center; and
a third solenoid valve arranged in the third branch, the third solenoid valve being configured to control to open or close the third branch based on the detection result of the psychrometer.

7. The system according to claim 6, wherein the cooling tower further comprises:
a dry cooler arranged above the condenser and connected to the second plate cooler, the dry cooler being configured to cool the circulating water.

8. A control method for the data center cooling system as claimed in claim 1, the control method comprising:
obtaining a dry-bulb temperature and a wet-bulb temperature inside the data center;
when the dry-bulb temperature is lower than a first threshold, controlling the second solenoid valve to be switched on, the first solenoid valve to be switched off, and the cooling water pump to be switched off;
when the dry-bulb temperature is not lower than the first threshold and the wet-bulb temperature is lower than a second threshold, controlling the first solenoid valve to be switched on, the second solenoid valve to be switched off, and the cooling water pump to be switched on; and
when the wet-bulb temperature is not lower than a third threshold, controlling the second solenoid valve to be switched on, the first solenoid valve to be switched off, and the cooling water pump to be switched on.

9. The control method according to claim 8 further comprising:
when the dry-bulb temperature is lower than the first threshold, controlling the first solenoid valve to be switched off, the second solenoid valve to be switched off, the cooling water pump to be switched off, and the third solenoid valve to be switched on.

10. A data center, comprising the data center cooling system as claimed in claim 1.
